(19) United States
(12) Patent Application Publication
(10) Pub. No.: US 2012/0037950 A1
(43) Pub. Date: Feb. 16, 2012

(54) LED WITH LOCAL PASSIVATION LAYERS

(76) Inventor: Yen-Chih CHIANG, Taichung City (TW)

(21) Appl. No.: 13/082,123

(22) Filed: Apr. 7, 2011

(30) Foreign Application Priority Data
Aug. 16, 2010 (TW) 099127363

(51) Int. Cl. H01L 33/44

(52) U.S. Cl. 257/100; 257/E33.06

(57) ABSTRACT

A LED with local passivation layers comprises a substrate, a light-emitting stack layer formed on the substrate, an electrode group formed on the light-emitting stack layer, and a first passivation layer formed on a side wall of the light-emitting stack layer. The light-emitting stack layer at least includes an n-type semiconductor layer, an active layer and a p-type semiconductor layer. The electrode group includes an n-type electrode and a p-type electrode. The n-type semiconductor layer has an exposed area where the n-type electrode is formed. The first passivation layer is distributed on a side wall of the light-emitting stack layer, which neighbors the exposed area, to protect the PN junction that is between the n-type semiconductor layer and the p-type semiconductor layer and is on the abovementioned side wall.

### FIELD OF THE INVENTION

The present invention relates to a LED, particularly to a LED with local passivation layers that are less likely to affect the light-emitting efficiency and wire-bonding force.

### BACKGROUND OF THE INVENTION

In LED (Light Emitting Diode), external voltage is applied to enable the recombination of electrons and holes in the active layer, whereby energy is emitted in form of light. LED has advantages of high light-emitting efficiency, long working time, small volume, low power consumption and superior color performance. LED has extensively replaced the traditional light-emitting elements in the climate of environmental protection and energy saving.

Refer to FIG. 1A a perspective view schematically showing a conventional LED structure. In the conventional LED structure, a light-emitting stack layer 11 is grown on a substrate 10 with a semiconductor process. An electrode group 12 is formed on the light-emitting stack layer 11. The light-emitting stack layer 11 includes an n-type semiconductor layer 111, an active layer 112 and a p-type semiconductor layer 113, which are sequentially formed above the substrate 11 bottom up. The active layer 112 and p-type semiconductor 113 are formed on a local area of the n-type semiconductor layer 111, whereby the n-type semiconductor layer 111 has an exposed area 114. The electrode group 12 includes an n-type electrode 121 and a p-type electrode 122. The p-type electrode 122 is formed on the p-type semiconductor layer 113 and has a solder pad 123. The n-type electrode 121 is formed on the exposed area 114 but does not contact the active layer 112 and the p-type semiconductor layer 113. The solder pad 123 and the n-type electrode 121 function as the electric contacts after the LED 1 is packaged.

Refer to FIG. 1B and FIG. 1C respectively a top view and a sectional view of the conventional LED structure in FIG. 1A. In the conventional technology, the entire light-emitting stack layer 11 is covered with a passivation layer 13 except the solder pad 123 and the n-type electrode 121 are exposed for electric connection. The passivation layer 13 protects the light-emitting stack layer 11 against damage coming from external environment. Further, the passivation layer 13 also functions as an electric insulation layer to prevent from current leakage caused by wire-bonding errors.

As shown in FIG. 1B, the passivation layer 13 is fully distributed over the light-emitting stack layer 12 except the solder pad 123 and the n-type electrode 121. Thus, the emitted light is impaired, and the light-emitting efficiency is reduced. As the exposed area of the n-type electrode 121 is narrowed, the boding force between the n-type electrode 121 and the metallic wire is decreased with the probability of pad peeling increasing in the wire-bonding process of the LED 1.

### SUMMARY OF THE INVENTION

One objective of the present invention is to provide a LED (Light Emitting Diode) with local passivation layers, wherein the passivation layers only partially cover the light-emitting surface, whereby the brightness of LED and the boding force between the chip and the metallic wire is less affected by the passivation layers.

The present invention proposes a LED with local passivation layers. In one embodiment, the LED of the present invention comprises a substrate, a light-emitting stack layer, an electrode group formed on the light-emitting stack layer, and a first passivation layer. The light-emitting stack layer at least includes an n-type semiconductor layer, an active layer and a p-type semiconductor layer. The n-type semiconductor layer has an exposed area. The electrode group includes an n-type electrode and a p-type electrode. The first passivation layer is distributed on a side wall of the light-emitting stack layer, and the abovementioned side wall is corresponding and adjacent to the n-type electrode. The first passivation layer covers the PN junction which is between the n-type semiconductor layer and the p-type semiconductor layer and is on the abovementioned side wall of the light-emitting stack layer.

In one embodiment, the LED of the present invention further comprises a second passivation layer. The second passivation layer is distributed on the non-pad area of the p-type electrode so as to expose a solder pad of the p-type electrode for electric connection.

In one embodiment, the LED of the present invention further comprises a third passivation layer. The third passivation layer is distributed on other side walls of the light-emitting stack layer except the side wall adjacent to the exposed area. The third passivation layer covers the PN junction which is between the n-type semiconductor layer and the p-type semiconductor layer and is along the side walls of the light-emitting stack layer, so as to protect the PN junction against debris.

In the present invention, the passivation layers only locally cover the LED and thus have less influence on the brightness of the LED. Besides, the passivation layers neither cover the contact areas of the electrode group nor decrease the exposed area of the electrode group in the present invention. Therefore, the passivation layers do not weaken the bonding force between the wires and the solder pads.

Below, the embodiments are described in detail in cooperation with the drawings to demonstrate the technical contents of the present invention.

### BRIEF DESCRIPTION OF THE DRAWINGS

The embodiments of the present invention are described in accompany with the following drawings.

FIG. 1A is a perspective view schematically showing a conventional LED structure;

FIG. 1B is a top view of the conventional LED structure in FIG. 1A;

FIG. 1C is a cross sectional view along Line K-K′ in FIG. 1B;

FIG. 2A is a perspective view schematically showing the structure of a LED with local passivation layers according to a first embodiment of the present invention;

FIG. 2B is a top view of the LED structure shown in FIG. 2A;

FIG. 2C is a cross sectional view along Line K-K′ in FIG. 2B;

FIG. 3A is a perspective view of the structure of a LED with local passivation layers according to a second embodiment of the present invention;

FIG. 3B is a top view of the LED structure shown in FIG. 3A; and FIG. 3C is a cross sectional view along Line K-K′ in FIG. 3B.

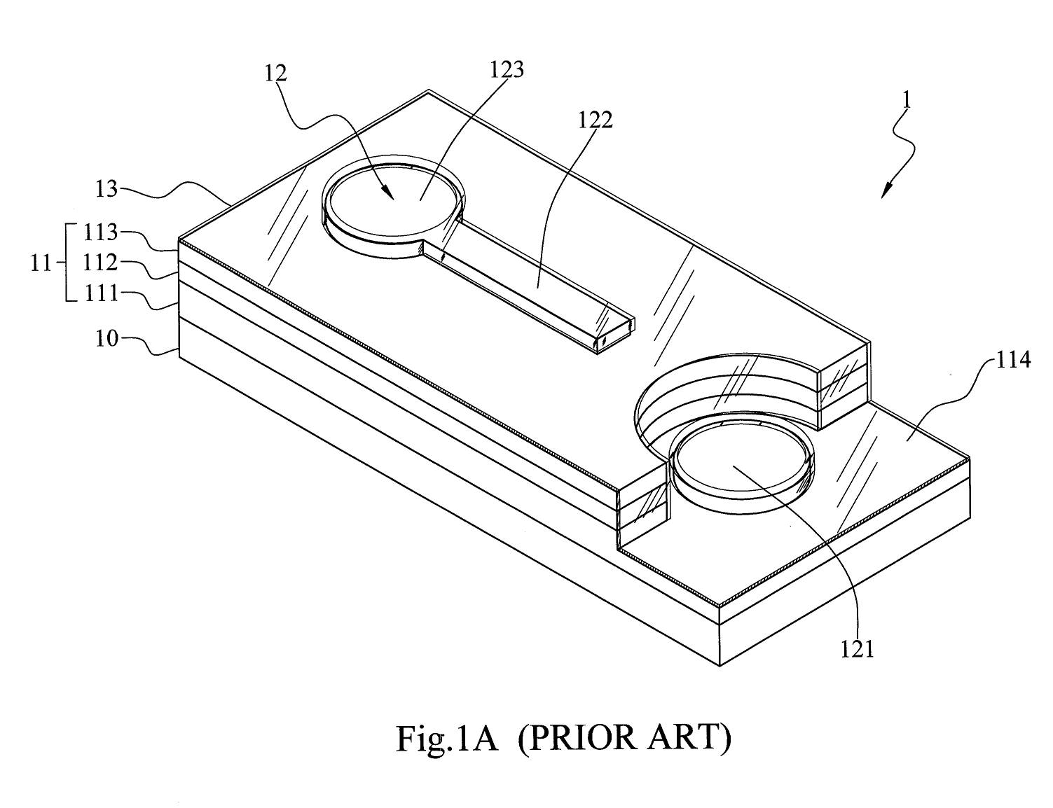

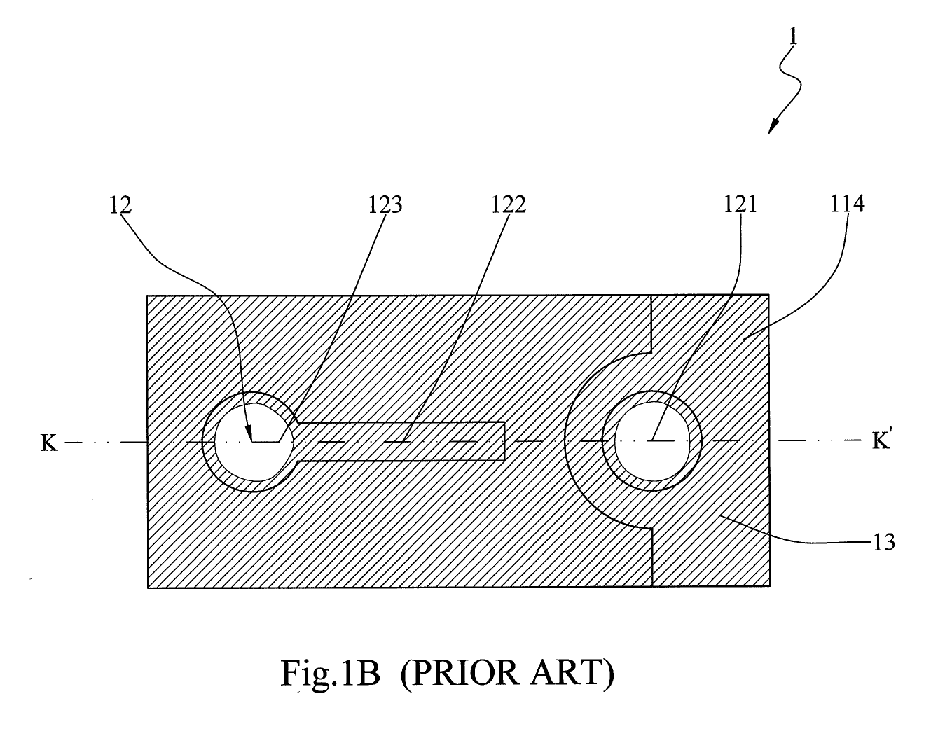

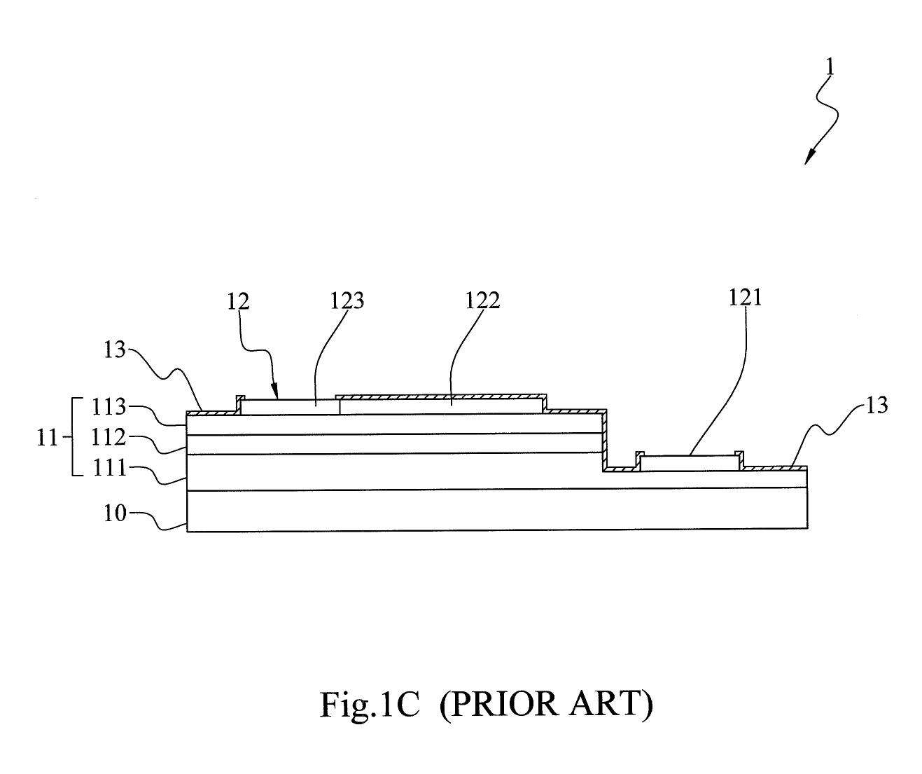

### DETAILED DESCRIPTION OF THE PREFERRED EMBODIMENTS

The technical contents of the present invention will be described in detail with the embodiments below. However, it should be understood: the embodiments are only to exemplify the present invention but not to limit the scope of the present invention; any equivalent modification or variation according to the spirit of the present invention is to be also included within the scope of the present invention.

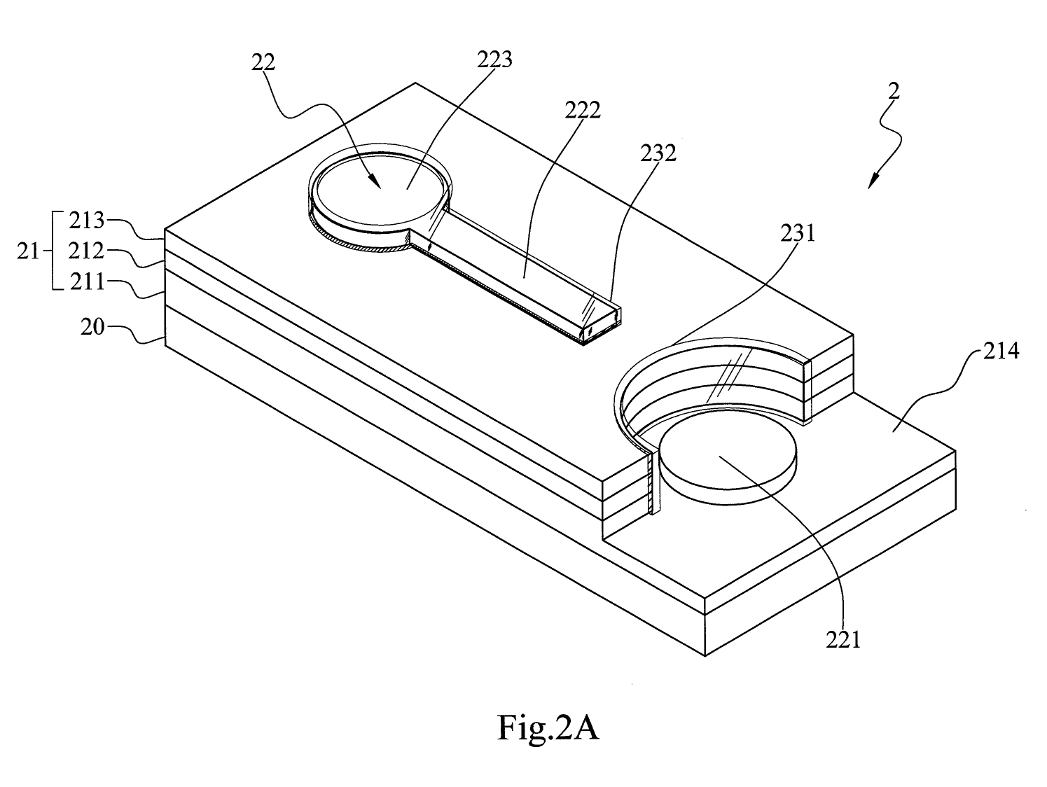

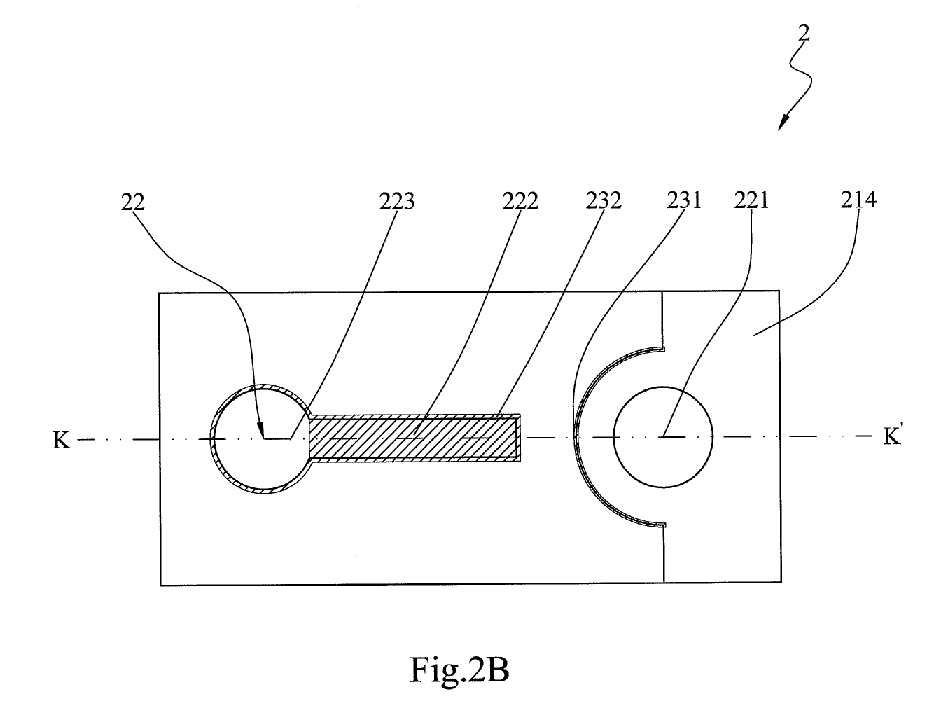

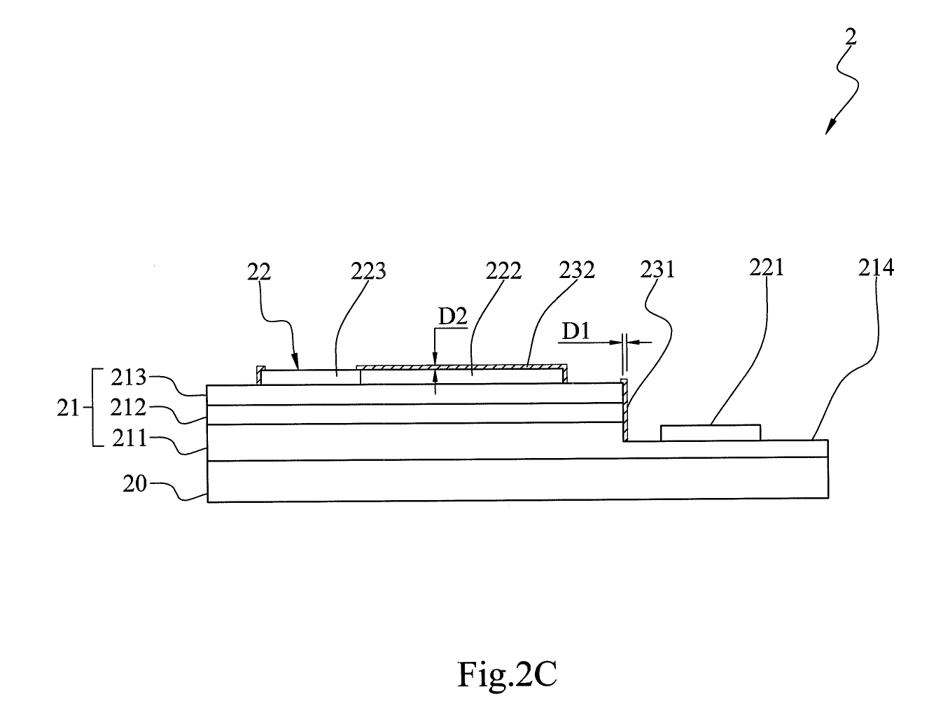

Refer to FIG. 2A a perspective view schematically showing the structure of a LED with local passivation layers according to a first embodiment of the present invention. The LED 2 of the present invention comprises a substrate 20, a light-emitting stack layer 21 and an electrode group 22. The light-emitting stack layer 21 is epitaxially grown on the substrate 20 with the semiconductor manufacturing technologies, including the deposition technology, the photolithographic technology, the etching technology, etc. The light-emitting stack layer 21 has several sub-layers. The light-emitting stack layer 21 at least includes an n-type semiconductor layer 211, an active layer 212 and a p-type semiconductor layer 213, which are sequentially formed over the substrate 20 bottom up. The technical details of the light-emitting stack layer 21, such as the materials, thicknesses and dimensions thereof, are only described as an example and will not be described in detail here.

The active layer 212 and the p-type semiconductor layer 213 are formed on a local area of the n-type semiconductor layer 211, whereby the n-type semiconductor layer 211 has an exposed area 214. The electrode group 22 includes an n-type electrode 221 and a p-type electrode 222. The p-type electrode 222 is formed on the p-type semiconductor layer 213 and has a solder pad 223. The n-type electrode 221 is formed on the exposed area 214 of the n-type semiconductor layer 211 but does not contact the active layer 212 and the p-type semiconductor layer 213. The solder pad 223 and the n-type electrode 221 function as electric contacts after the LED 2 is packaged.

Refer to FIG. 2B and FIG. 2C, which are respectively a top view of the structure in FIG. 2A and a cross sectional view along Line K-K′ in FIG. 2B. In the first embodiment, the LED 2 further comprises a first passivation layer 231. The first passivation layer 231 is formed on a side wall of the light-emitting stack layer 21, and the abovementioned side wall is corresponding and adjacent to the n-type electrode 221. The first passivation layer 231 covers the PN junction which is between the n-type semiconductor layer 211 and the p-type semiconductor layer 213 and is on the above-mentioned side wall of the light-emitting stack layer 21. In the present invention, the first passivation layer 231 does not cover the top surface of the n-type electrode 221 so as to expose the n-type electrode 221.

In the first embodiment, the LED 2 further comprises a second passivation layer 232. The second passivation layer 232 is distributed over the non-pad area of the p-type electrode 222 so as to expose the solder pad 223 for electric connection. It should be explained particularly: The solder pad 223 is defined to be the exposed area for wire-bonding of the p-type electrode 222; the non-pad area of the p-type electrode 222 is thus the region where the solder pad 223 is excluded from the p-type electrode 222, such as the region of the p-type electrode 222 for increasing current distribution.

For an identical electrode size, material and fabrication process, wire-bonding error causes greater current leakage in the n-type electrode 221 than in the p-type electrode 222. Therefore, the first passivation layer 231 is addressed to the n-type electrode 221 and only locally covers the PN junction on the side wall of the light-emitting stack layer 21. In such a case, the entire top surface of the LED 2 is still naked, including the top surface of the n-type electrode 221. Thus, the brightness of the LED 2 is less affected, and the short circuit-prevention effect of the passivation layer is still preserved.

In one embodiment, the first/second passivation layer 231/232 is made of a transparent and insulating material, such as silicon nitride, silicon oxide, or silicon oxynitride. If the locally-covering passivation layers still affect the brightness of the LED 2, a high-transparency and high-reflectivity material may be used selectively as the material of the first/second passivation layer 231/232. It should be explained particularly: in the above-mentioned silicon oxynitride (SiOxNy), wherein y=1−x, x: 0˜1 and y: 1˜0; the thickness (D1) of the first passivation layer 231 and the thickness (D2) of the second passivation layer 232 are smaller than 0.5 μm. Refer to FIG. 2C. The first passivation layer 231 and the second passivation thickness 232 may respectively have different thicknesses to satisfy different design requirements. In fabricating the first/second passivation layer 231/232, the photolithographic technology is used to define the pattern of the first/second passivation layer 231/232 firstly; the abovementioned insulating material, such as silicon nitride, silicon oxide or silicon oxynitride, is then deposited on the defined area with the CVD (Chemical Vapor Deposition) technology, the PECVD (Plasma Enhanced Chemical Vapor Deposition) technology, or the LPCVD (Low Pressure Chemical Vapor Deposition) technology, whereby the passivation layers are accurately formed without covering the areas that are intended to be exposed.

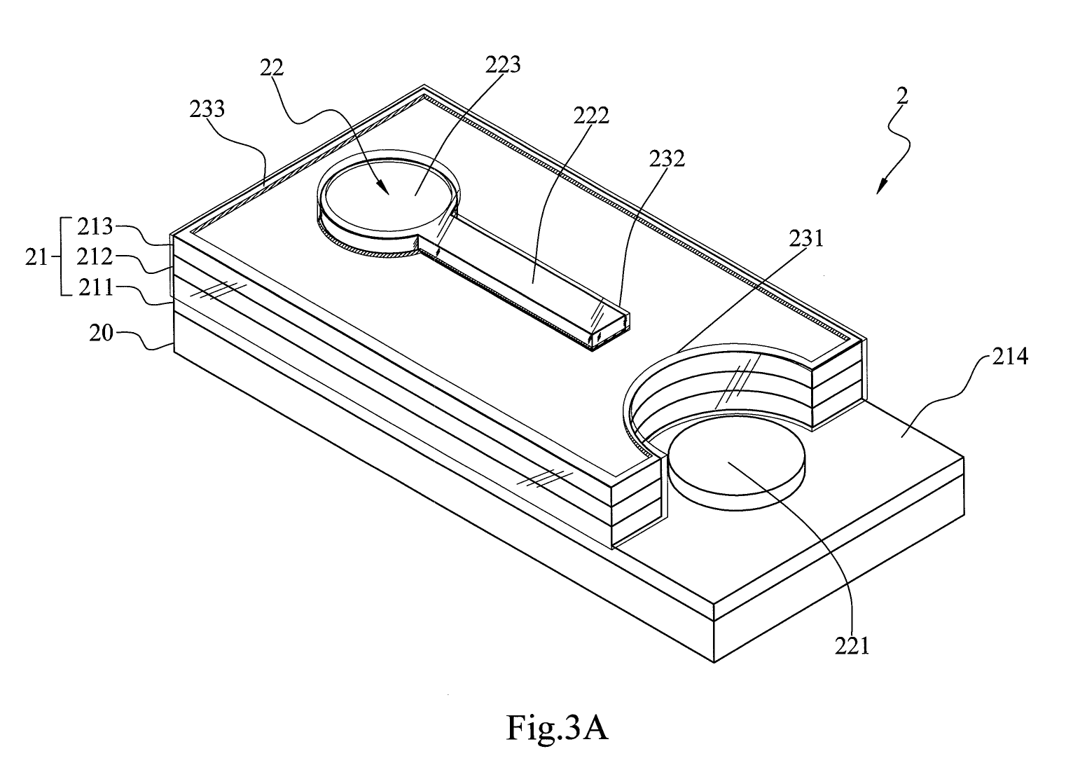

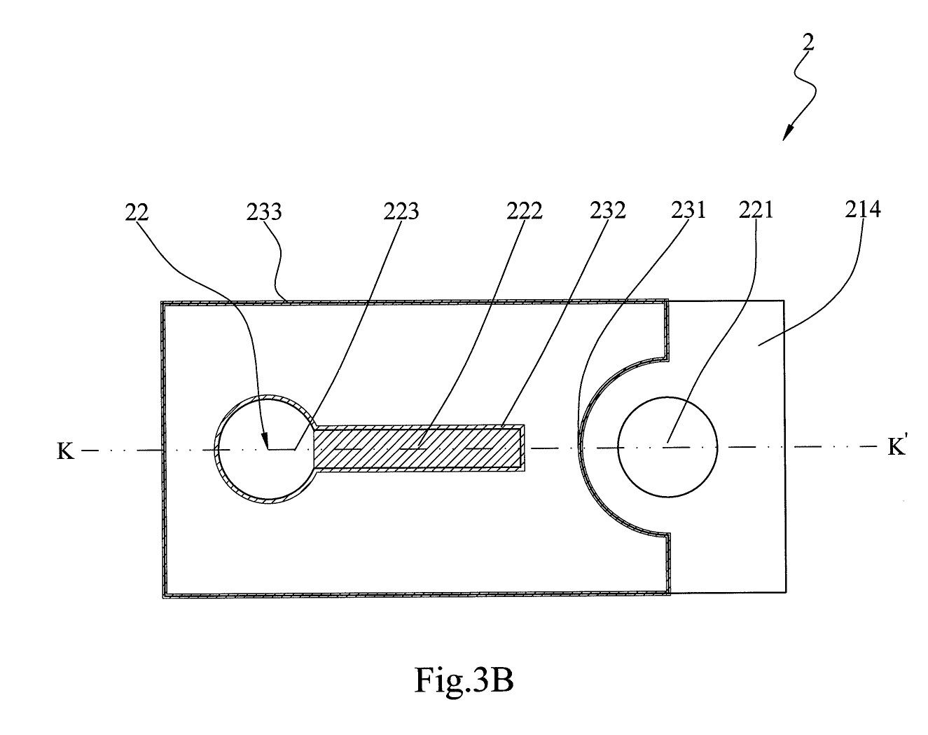

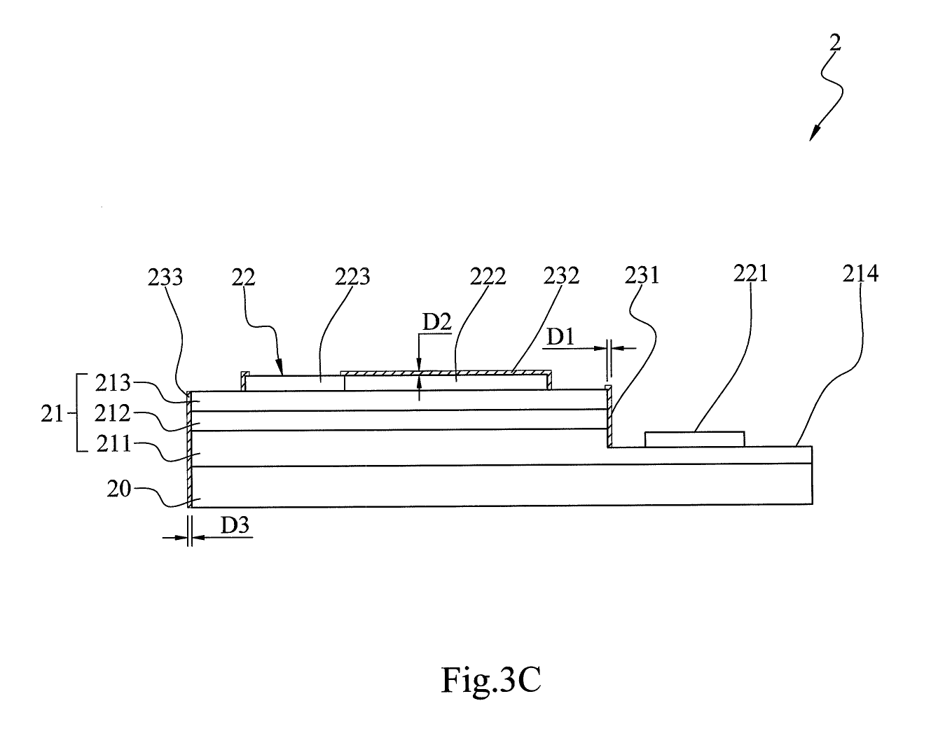

Refer to FIGS. 3A-3C respectively a perspective view, a top view and a cross sectional view of a LED with local passivation layers according to a second embodiment of the present invention. Herein, the similarities of the first embodiment and the second embodiment will not repeat. In the second embodiment, the LED 2 further comprises a third passivation layer 233. The third passivation layer 233 is distributed along other side walls of the light-emitting stack layer 21 except the side wall where the first passivation layer 231 is distributed, whereby the PN junction between the n-type semiconductor layer 211 and the p-type semiconductor layer 213 is covered. It should be mentioned particularly: the thickness (D3) of the third passivation layer 233 is also smaller than 0.5 μm. Similarly, the first passivation layer 231, the second passivation thickness 232 and the third passivation layer 233 may respectively have different thicknesses to satisfy different design requirements.

After a wafer mass-fabrication, the wafer is spilt along the scribed channels to singulate the LED chips to facilitate the later packing process. In the splitting process, the produced debris is likely to damage the PN junctions on the side walls of the light-emitting stack layers 21, which may cause electric problems, such as current leakage. The third passivation layer 233 of the present invention, which is formed along the side walls of the light-emitting stack layer 21, can protect the PN junctions against the debris. The semiconductor manufacturing technologies, such as the photolithographic technology and etching technology, are used to define the areas of the third passivation layers 233. Then, the passivation layers are grown on the defined areas with a deposition method. The first passivation layer 231, second passivation layer 232 and third passivation layer 233 may be simultaneously or separately defined and formed. It should be mentioned particularly: As the third passivation layer 233 is distributed along the side walls of the light-emitting stack layer 21, the coverage of the third passivation layer 233 includes the area where the first passivation layer 231 is distributed.

In the present invention, the first passivation layer 231 only covers the side wall of the light-emitting stack layer 21, which neighbors and corresponds to the exposed area 214, with the entire top surface of the LED 2 still being exposed. Therefore, the brightness of the LED 2 is less affected by the first passivation layer 231. Further, the present invention is exempted from the conventional problem that the bonding force is decreased by the reduced exposed area.

The embodiments described above are only to exemplify the present invention but not to limit the scope of the present invention. Any equivalent modification or variation according to the spirit of the present invention is to be also included within the scope of the present invention.

What is claimed is:

1. A light emitting diode with local passivation layers, comprising
a light-emitting stack layer at least including an n-type semiconductor layer, an active layer and a p-type semiconductor layer, wherein the n-type semiconductor layer has an exposed area;
an electrode group which is located on the light-emitting stack layer and includes an n-type electrode and a p-type electrode; and
a first passivation layer distributed on a side wall of the light-emitting stack layer to cover a PN junction between the n-type semiconductor layer and the p-type semiconductor layer, wherein the side wall is corresponding and adjacent to the n-type electrode.

2. The light emitting diode with local passivation layers according to claim 1, wherein the first passivation layer is made of a material selected from a group consisting of silicon nitride, silicon oxide, and silicon oxynitride.

3. The light emitting diode with local passivation layers according to claim 1, wherein a first pattern where the first passivation layer is distributed is defined by a semiconductor process to provide the first passivation layer to be grown on the defined pattern.

4. The light emitting diode with local passivation layers according to claim 1 further comprising a second passivation layer distributed on a non-pad area of the p-type electrode.

5. The light emitting diode with local passivation layers according to claim 4, wherein the thickness of the first passivation layer and the thickness of the second passivation layer are smaller than 0.5 μm.

6. The light emitting diode with local passivation layers according to claim 4, wherein the second passivation layer is made of a material selected from a group consisting of silicon nitride, silicon oxide, and silicon oxynitride.

7. The light emitting diode with local passivation layers according to claim 4, wherein a second pattern where the second passivation layer is distributed is defined by a semiconductor process to provide the second passivation layer to be grown on the defined pattern.

8. The light emitting diode with local passivation layers according to claim 1 further comprising a third passivation layer distributed along other side walls of the light-emitting stack layer except the side wall where the first passivation layer is distributed, whereby the PN junction between the n-type semiconductor layer and the p-type semiconductor layer is covered.

9. The light emitting diode with local passivation layers according to claim 8, wherein the third passivation layer is made of a material selected from a group consisting of silicon nitride, silicon oxide, and silicon oxynitride.

10. The light emitting diode with local passivation layers according to claim 8, wherein a third pattern where the third passivation layer is distributed is defined by a semiconductor process to provide the third passivation layer to be grown on the defined pattern.

11. The light emitting diode with local passivation layers according to claim 8, wherein a pattern where the third passivation layer has a thickness smaller than 0.5 μm.
